(19) United States
(12) Patent Application Publication
(10) Pub. No.: US 2006/0043361 A1
(43) Pub. Date: Mar. 2, 2006

(54) White light-emitting organic-inorganic hybrid electroluminescence device comprising semiconductor nanocrystals

(75) Inventors: Sung Hun Lee, Gyeonggi-Do (KR); Eun Joo Jang, Daejeon-Si (KR); Shin Ae Jun, Gyeonggi-Do (KR); Seong Jae Choi, Seoul (KR); Lyung Sun Pu, Gyeonggi-Do (KR); Tae Kyung Ahn, Seoul (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Gyeonggi-Do (KR)

(21) Appl. No.: 11/073,718

(22) Filed: Mar. 8, 2005

(30) Foreign Application Priority Data
Aug. 25, 2004 (KR) 10-2004-0067038

(51) Int. Cl. H01L 29/08; H01J 63/04

(52) U.S. Cl. 257/40; 313/504

(57) ABSTRACT

A white light-emitting organic-inorganic hybrid electroluminescence device which has nanocrystals as illuminants. According to the device, a semiconductor nanocrystal layer composed of at least one kind of nanocrystals, a hole transport layer and/or an electron transport layer simultaneously emit light to produce white light, or a semiconductor nanocrystal layer composed of at least two kinds of nanocrystals emits light at different wavelengths to produce white light. The device can be used as a backlight unit for a liquid crystal display, or can be used to manufacture an illuminator.

### BACKGROUND OF THE INVENTION

This non-provisional application claims priority under 35 U.S.C. § 119(a) on Korean Patent Application No. 2004-47038 filed on Aug. 25, 2004, which is herein expressly incorporated by reference.

1. Field of the Invention

Embodiments of the present invention relate to a white light-emitting organic-inorganic hybrid electroluminescence device comprising nanocrystals as illuminants, and more particularly to a white light-emitting organic-inorganic hybrid electroluminescence device comprising semiconductor nanocrystals wherein a semiconductor nanocrystal layer composed of at least one kind of nanocrystals, a hole transport layer and/or an electron transport layer simultaneously emit light to produce white light, or a semiconductor nanocrystal layer that is light-emitting (i.e., luminescent layer) composed of at least two kinds of nanocrystals emits light at different wavelengths to produce white light.

2. Description of the Related Art

A nanocrystal is defined as a material having a crystal size at the nanometer-scale level and consists of several hundred to several thousand atoms. Since the small-sized nanocrystal has a large surface area per unit volume, most of the atoms constituting the nanocrystal are present at the surface of the nanocrystal. Based on this structure, the nanocrystal exhibits quantum confinement effects, and shows electrical, magnetic, optical, chemical and mechanical properties different from those inherent to the constituent atoms of the nanocrystal. That is, the control over the physical size of the nanocrystal enables the control of various properties.

Conventional vapor deposition processes, including metal organic chemical deposition (MOCVD) and molecular beam epitaxy (MBE), have been used to prepare nanocrystals. As another process for preparing nanocrystals, a wet chemistry technique has made remarkable progress.

In nanocrystal electroluminescence devices reported hitherto, the nanocrystals are used as luminescent materials, or are allowed to have a light emission function in combination with a charge transport function, enabling realization of monochromic organic electroluminescence devices.

For example, the first organic electroluminescence device comprising a large number of semiconductor nanocrystals was suggested in PCT publication WO 03/084292. This publication, however, does not disclose a white light-emitting organic electroluminescence device.

U.S. Pat. No. 5,537,000 describes an electroluminescence device without an electron transport organic layer in which a multilayer of nanocrystals acts as both a light-emitting layer and an electron transport layer, and the wavelengths of emitted light are dependent upon a voltage applied to the device.

Further, U.S. Pat. No. 6,608,439 discloses an integrated light-emitting diode color display in which nanocrystals used as a color-conversion layer absorb monochrome and short-wavelength light emitted from an organic layer, and then emit photoluminescence (PL) at a different wavelength. However, the device is not driven by electroluminescence.

U.S. Pat. No. 6,049,090 describes a device wherein a mixed layer of nanocrystals and a matrix as a light-emitting layer is disposed between two electrodes. According to the device, the matrix is selected to have a wider bandgap energy, a higher conduction band energy level and a lower valence band energy level than the nanocrystals so as to allow the nanocrystals to emit light well and trap electrons and holes, thereby enhancing the luminescence efficiency of the device.

As stated earlier, the related art organic luminescence devices comprising nanocrystals are devices emitting monochromatic light. None of the above patents disclose a white light-emitting electroluminescence device comprising semiconductor nanocrystals.

### OBJECTS AND SUMMARY

The present inventors have earnestly and intensively conducted research to develop a white light-emitting electroluminescence device comprising semiconductor nanocrystals, and as a result, have found that a white light-emitting organic-inorganic hybrid electroluminescence device wherein a semiconductor nanocrystal layer, a hole transport layer and/or an electron transport layer simultaneously emit light to achieve white light emission, or semiconductor nanocrystals with different sizes and compositions simultaneously emit light at different wavelengths to achieve white light emission. Embodiments of the present invention are based on this finding.

Therefore, a feature of the embodiments of the present invention is to provide a white light-emitting organic-inorganic hybrid electroluminescence device comprising semiconductor nanocrystals.

Another feature of the embodiments of the present invention is to provide a full-color display comprising the electroluminescence device and a color filter.

Another feature of the embodiments of the present invention is to provide an illuminator comprising the electroluminescence device.

Still another feature of the embodiments of the present invention is to provide a liquid crystal display comprising the electroluminescence device as a backlight unit.

In accordance with one aspect of the present invention, there is provided a white light-emitting organic-inorganic hybrid electroluminescence device, comprising:
(i) a hole-injecting electrode; (ii) a hole transport layer; (iii) a semiconductor nanocrystal layer; (iv) an electron transport layer; and (v) an electron-injecting electrode, which are formed in this order from the bottom, wherein at least one layer selected from the semiconductor nanocrystal layer, the hole transport layer and the electron transport layer emits light to achieve white light emission.

In accordance with another aspect of the present invention, there is provided a white light-emitting organic-inorganic hybrid electroluminescence device, comprising: (i) a hole-injecting electrode; (ii) a hole transport layer; (iii) a semiconductor nanocrystal layer; (iv) an electron transport layer; and (v) an electron-injecting electrode, which are formed in this order from the bottom, wherein the semiconductor nanocrystal layer is composed of at least two kinds of semiconductor nanocrystals with different sizes and/or compositions, and the semiconductor nanocrystals simultaneously emit light at different wavelengths to achieve white light emission.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view schematically showing the structure of a white light-emitting organic-inorganic hybrid electroluminescence device according to one embodiment of the present invention; and

FIGS. 2 to 5 are electroluminescence spectra of organic-inorganic hybrid electroluminescence devices fabricated in Examples 1 to 4 of the present invention in response to the changes in the voltages applied to the devices, respectively.

### DESCRIPTION OF THE PREFERRED EMBODIMENTS

Embodiments of the present invention will now be described in more detail with reference to the accompanying drawings.

A white light-emitting organic-inorganic hybrid electroluminescence device according to embodiments of the present invention is characterized in that a nanocrystal layer composed of at least one kind of semiconductor nanocrystals, a hole transport layer and/or an electron transport layer jointly emit light to produce white light, or at least two kinds of semiconductor nanocrystals producing different colors of light simultaneously emit light to produce white light.

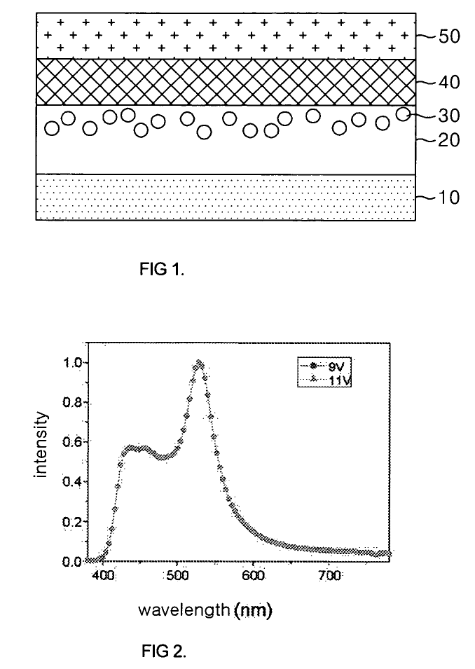

FIG. 1 is a cross-sectional view schematically showing the structure of the white light-emitting organic-inorganic hybrid electroluminescence device according to one embodiment of the present invention. Referring to FIG. 1, the electroluminescence device of the present invention comprises a hole-injecting electrode 10, a hole transport layer 20, a semiconductor nanocrystal layer 30, an electron transport layer 40, and an electron-injecting electrode 50, which are formed in this order from the bottom. Optionally, the electroluminescence device of the present invention may further comprise a hole-blocking layer (not shown) interposed between the semiconductor nanocrystal layer 30 and the electron transport layer 40. When a voltage is applied to the electroluminescence device, the hole-injecting electrode 10 injects holes into the hole transport layer 20, and the electron-injecting electrode 50 injects electrons into the electron transport layer 40. The injected holes are combined with the injected electrons at the same molecules to form excitons, and then the excitons are recombined to emit light. In the electroluminescence device according to embodiments of the present invention, a region where the excitons are recombined is formed over the nanocrystal layer, the hole transport layer and/or the electron transport layer to achieve white light emission. Alternatively, the region may be restricted to the nanocrystal layer to allow at least two kinds of nanocrystals to emit light at different wavelengths, thereby achieving white light emission.

The hole-injecting electrode 10 can be formed of a conductive metal or an oxide thereof, for example, indium tin oxide (ITO), indium zinc oxide (IZO), nickel (Ni), platinum (Pt), gold (Au), silver (Ag), or iridium (Ir).

Suitable materials for the hole transport layer 20 are materials commonly used in the art. Specific examples of materials for the hole transport layer 20 include, but are not limited to, poly(3,4-ethylenedioxythiophene) (PEDOT)/polystyrene para-sulfonate (PSS), poly-N-vinylcarbazole derivatives, polyphenylenevinylene derivatives, polyparaphenylene derivatives, polymethacrylate derivatives, poly(9,9-dioctylfluorene) derivatives, poly(spiro-fluorene) derivatives, triarylamine derivatives, copper phthalocyanine derivatives, and starburst-type compounds. The thickness of the hole transport layer 20 is preferably in the range of 10 nm to 100 nm.

Nanocrystals that can be used in the present invention include all nanocrystals prepared by a wet chemistry technique. For example, the nanocrystals may be prepared by adding a corresponding metal precursor to an organic solvent in the absence or presence of a dispersant and growing crystals at a constant temperature. Specifically, the semiconductor nanocrystal layer 30 that is light-emitting is made of at least one material selected from the group consisting of Group II-IV compound semiconductor nanocrystals, such as CdS, CdSe, CdTe, ZnS, ZnSe, ZnTe, HgS, HgSe and HgTe, Group III-V compound semiconductor nanocrystals, such as GaN, GaP, GaAs, InP and InAs, Group IV-VI compound semiconductor nanocrystals, such as PbS, PdSe and PbTe, and Group IV semiconductor nanocrystals, such as Si and Ge. As needed, there can be used a mixture of two or more nanocrystals. If the semiconductor nanocrystal layer 30 that is light-emitting is made of a mixture of two or more nanocrystals, the nanocrystals may exist in the state of a simple mixture, fused crystals in which the nanocrystals are partially present in the same crystal structure, e.g., core-shell structured nanocrystals and gradient-structured nanocrystals, or an alloy.

In the case where the semiconductor nanocrystal layer 30, the hole transport layer 20 and/or the electron transport layer 40 jointly emit light to produce white light, the semiconductor nanocrystal layer is composed of at least one kind of nanocrystals. Alternatively, the semiconductor nanocrystal layer can be composed of a mixture of at least two kinds of nanocrystals having different sizes, compositions, shapes and/or structures.

On the other hand, when the semiconductor nanocrystal layer 30 only acts as a light-emitting layer to produce white light, the semiconductor nanocrystal layer 30 emits light at different wavelengths from at least two kinds of nanocrystals having different sizes, compositions, shapes and/or structures, thereby achieving white light emission.

The thickness of the semiconductor nanocrystal layer 30 is preferably in the range of 3 nm to 100 nm.

The electron transport layer 40 can be formed of a material commonly used in the art. As materials constituting the electron transport layer 40, there may be mentioned, for example, oxazoles, isooxazoles, triazoles, isothiazoles, oxydiazoles, thiadiazoles, perylenes, and aluminum complexes, including tris(8-hydroxyquinoline)-aluminum (Alq3), bis(2-methyl-8-quinolinatho)(p-phenyl-phenolato) aluminum (Balq) and bis(2-methyl-8-quinolinato)(triphenylsiloxy) aluminum (III) (Salq). The thickness of the electron transport layer 40 is preferably between 10 nm and 100 nm.

As a material for the electron-injecting electrode 50, there can be used a low work function metal. Examples of the low work function metal include, but are not limited to, I, Ca, Ba, Ca/Al, LiF/Ca, LiF/Al, BaF₂/Al, BaF₂/Ca/Al, Al, Mg, and Ag:Mg alloys. The thickness of the electron-injecting electrode is preferably in the range of 50 nm to 300 nm.

Examples of suitable materials for the hole-blocking layer (not shown) include those commonly used in the art. Specific examples include, but are not limited to, triazoles, e.g., 3-phenyl-4-(1′-naphthyl)-5-phenyl-1,2,4-triazole (TAZ), phenanthrolines, e.g., 2,9-dimethyl-1,10-phenanthroline (BCP), imidazoles, oxadiazoles, and aluminum complexes. The thickness of the hole-blocking layer (not shown) is preferably in the range of 5 nm to 50 nm.

The fabrication of the organic-inorganic hybrid electroluminescence device according to embodiments of the present invention does not require particular fabrication apparatuses and methods, in addition to the formation of the light-emitting layer. The organic-inorganic hybrid electroluminescence device of the present invention can be fabricated in accordance with conventional fabrication methods using common light-emitting materials.

The white light-emitting organic-inorganic hybrid electroluminescence device comprising semiconductor nanocrystals according to embodiments of the present invention is fabricated in accordance with the following procedure. First, a material for a hole transport layer and semiconductor nanocrystals are dispersed in an organic solvent (e.g., chlorobenzene), and then the dispersion is coated on a hole-injecting electrode 10 by spin coating, dip coating, spray coating, blade coating, or the like, to form a thin film. Thereafter, the thin film is sufficiently dried by post treatment, such as heat treatment to form substantially complete and independent hole transport layer 20 and semiconductor nanocrystal layer 30. At this time, the semiconductor nanocrystals naturally float upward and thus phase separation takes place between the material for the hole transport layer and the semiconductor nanocrystals. An electron transport layer 40 is formed on the semiconductor nanocrystal layer 30 by thermal deposition, molecular deposition, or chemical deposition. An electron-injecting electrode 50 is formed on the electron transport layer 40 to fabricate the final white light-emitting organic-inorganic hybrid electroluminescence device. If needed, a hole-blocking layer (not shown) may be formed after the formation of the semiconductor nanocrystal layer 30 and prior to the formation of the electron transport layer 40.

The white light-emitting organic-inorganic hybrid electroluminescence device comprising semiconductor nanocrystals according to embodiments of the present invention can be combined with a color filter to manufacture a full color display, can be used as a backlight unit for a liquid crystal display, or can be used to manufacture an illuminator.

Hereinafter, embodiments of the present invention will be specifically explained with reference to the following preparative examples and examples. However, these examples are given for the purpose of illustration and are not to be construed as limiting the scope of the invention.

### PREPARATIVE EXAMPLE 1

### Preparation of 520 nm Light-Emitting CdSe/ZnS Nanocrystals

16 g of trioctyl amine (hereinafter, referred to as ‘TOA’), 0.5 g of oleic acid, and 0.4 mmol of cadmium oxide were simultaneously charged into a 125 ml flask equipped with a reflux condenser. The reaction temperature of the mixture was adjusted to 300° C. with stirring. Separately, a selenium (Se) powder was dissolved in trioctyl phosphine (hereinafter, referred to as ‘TOP’) to obtain a Se-TOP complex solution (Se concentration: about 0.2M), and 1 ml of the Se-TOP complex solution was rapidly fed to the previous reaction mixture. Stirring was continued for about one minute. After the reaction was completed, the reaction mixture was cooled to room temperature as rapidly as possible. Ethanol as a non-solvent was added to the reaction mixture, and the resulting mixture was then centrifuged. After the obtained precipitates were separated from the supernatant, they were dispersed in toluene to prepare a 1 wt % dispersion (“core solution”).

On the other hand, 16 g of TOA, 0.5 g of oleic acid, and 0.1 mmol of zinc acetate were simultaneously charged into a 125 ml flask equipped with a reflux condenser. The reaction temperature of the mixture was adjusted to 240° C. with stirring. 1 ml of the core solution was rapidly introduced into the flask. Separately, a sulfur (S) powder was dissolved in TOP to obtain an S-TOP complex solution (S concentration: about 1.0M). 1 ml of the S-TOP complex solution was slowly fed to the previous reaction mixture. Stirring was continued for one hour. After the reaction was completed, the reaction mixture was cooled to room temperature as rapidly as possible. Ethanol as a non-solvent was added to the reaction mixture, and the resulting mixture was then centrifuged. After the obtained precipitates were separated from the supernatant, they were dispersed in toluene to prepare a 1 wt % dispersion of nanocrystals. The nanocrystal dispersion emitted orange light under a UV lamp at 365 nm. The nanocrystal dispersion showed a photoluminescence peak at around 520 nm of which full-width at half maximum (FWHM) was about 30 nm.

### PREPARATIVE EXAMPLE 2

### 470 nm Light-Emitting CdSeS/ZnS Nanocrystals

16 g of TOA, 0.5 g of oleic acid, and 0.4 mmol of cadmium oxide were simultaneously charged into a 125 ml flask equipped with a reflux condenser. The reaction temperature of the mixture was adjusted to 300° C. with stirring. Separately, a selenium (Se) powder was dissolved in TOP to obtain a Se-TOP complex solution (Se concentration: about 0.1M), and a sulfur (S) powder was dissolved in TOP to obtain an S-TOP complex solution (S concentration: about 0.1M). A mixture of the S-TOP complex solution (0.9 ml) and the Se-TOP complex solution (0.1 ml) were rapidly fed to the previous reaction mixture. Stirring was continued for about 4 minutes. After the reaction was completed, the reaction mixture was cooled to room temperature as rapidly as possible. Ethanol as a non-solvent was added to the reaction mixture, and the resulting mixture was then centrifuged. After the obtained precipitates were separated from the supernatant, they were dispersed in toluene to prepare a 1 wt % core solution.

On the other hand, 16 g of TOA, 0.5 g of oleic acid, and 0.1 mmol of zinc acetate were simultaneously charged into a 125 ml flask equipped with a reflux condenser. The reaction temperature of the mixture was adjusted to 240° C. with stirring. 1 ml of the core solution was rapidly introduced into the flask. Separately, a sulfur (S) powder was dissolved in TOP to obtain an S-TOP complex solution (S concentration: about 1.0M). 1 ml of the S-TOP complex solution was slowly fed to the previous reaction mixture. Stirring was continued for one hour. After the reaction was completed, the reaction mixture was cooled to room temperature as rapidly as possible. Ethanol as a non-solvent was added to the reaction mixture, and the resulting mixture was then centrifuged. After the obtained precipitates were separated from the supernatant, they were dispersed in toluene to prepare a 1 wt % dispersion of nanocrystals.

The nanocrystal dispersion emitted blue light under a UV lamp at 365 nm. The nanocrystal dispersion showed a photoluminescence peak at around 470 nm of which FWHM was about 30 nm.

### PREPARATIVE EXAMPLE 3

### 590 nm Light-Emitting CdSeS/ZnS Nanocrystals

16 g of TOA, 0.5 g of oleic acid, and 0.4 mmol of cadmium oxide were simultaneously charged into a 125 ml flask equipped with a reflux condenser. The reaction temperature of the mixture was adjusted to 300° C. with stirring. Separately, a selenium (Se) powder was dissolved in TOP to obtain a Se-TOP complex solution (Se concentration: about 0.25M), and a sulfur (S) powder was dissolved in TOP to obtain an S-TOP complex solution (S concentration: about 1.0M). A mixture of the S-TOP complex solution (0.5 ml) and the Se-TOP complex solution (0.5 ml) were rapidly fed to the previous reaction mixture. Stirring was continued for about 4 minutes. After the reaction was completed, the reaction mixture was cooled to room temperature as rapidly as possible. Ethanol as a non-solvent was added to the reaction mixture, and the resulting mixture was then centrifuged. After the obtained precipitates were separated from the supernatant, they were dispersed in toluene to prepare a 1 wt % core solution.

On the other hand, 16 g of TOA, 0.5 g of oleic acid, and 0.1 mmol of zinc acetate were simultaneously charged into a 125 ml flask equipped with a reflux condenser. The reaction temperature of the mixture was adjusted to 240° C. with stirring. 1 ml of the core solution was rapidly introduced into the flask. Separately, a sulfur (S) powder was dissolved in TOP to obtain an S-TOP complex solution (S concentration: about 1.0M). 1 ml of the S-TOP complex solution was slowly fed to the previous reaction mixture. Stirring was continued for one hour. After the reaction was completed, the reaction mixture was cooled to room temperature as rapidly as possible. Ethanol as a non-solvent was added to the reaction mixture, and the resulting mixture was then centrifuged. After the obtained precipitates were separated from the supernatant, they were dispersed in toluene to prepare a 1 wt % dispersion of nanocrystals.

The nanocrystal dispersion emitted orange light under a UV lamp at 365 nm. The nanocrystal dispersion showed a photoluminescence peak at around 590 nm of which FWHM was about 30 nm.

### EXAMPLE 1

### Fabrication of Organic-Inorganic Hybrid Electroluminescence Device Wherein Hole Transport Layer and Nanocrystals Simultaneously Emit Light

First, a glass substrate on which ITO was patterned was sequentially washed with a neutral detergent, deionized water and isopropyl alcohol, and was then subjected to UV-ozone treatment. poly(9,9′-dioctylfluorene-co-N-(4-butylphenyl)diphenylamine (TFB) and the 520 nm light-emitting CdSe/ZnS nanocrystals prepared in Preparative Example 1 in a weight ratio of 1:1 were dispersed in chlorobenzene to a 1 wt % dispersion. The dispersion was spin-coated on the substrate to a thickness of about 50 nm to form a thin film, and thereafter the thin film was baked at 180° C. for 10 minutes to form a hole transport layer and a semiconductor nanocrystal layer that is light-emitting.

3-phenyl-4-(1′-naphthyl)-5-phenyl-1,2,4-triazole (TAZ) was deposited on the completely dried light-emitting layer to form a hole-blocking layer having a thickness of 10 nm, and then tris(8-hydroxyquinoline)aluminum (Alq3) was deposited on the hole-blocking layer to a thickness of about 20 nm to form an electron transport layer. LiF and aluminum were sequentially deposited on the electron transport layer to thicknesses of 1 nm and 200 nm, respectively, to form an electrode, thereby fabricating the final organic-inorganic hybrid electroluminescence device.

FIG. 2 shows electroluminescence spectra of the organic-inorganic hybrid electroluminescence device in response to the changes in the voltages applied to the device. As shown in FIG. 2, the spectra show that excitons were recombined over the hole transport layer and the nanocrystal layer to simultaneously emit light. In this example, the nanocrystals emitted light at about 528 nm, and the TFB emitted light at about 440 nm.

### EXAMPLE 2

### Fabrication of Organic-Inorganic Hybrid Electroluminescence Device Wherein Electron Transport Layer and Nanocrystals Simultaneously Emit Light

First, a glass substrate on which ITO was patterned was sequentially washed with a neutral detergent, deionized water and isopropyl alcohol, and was then subjected to UV-ozone treatment. N,N′-bis(3-methylphenyl)-N,N′-bis(phenyl)benzidine (TPD) and the 470 nm light-emitting nanocrystals prepared in Preparative Example 2 in a weight ratio of 1:1 were dissolved in chloroform to prepare a 1 wt % solution. The solution was spin-coated on the substrate to form a thin film, and thereafter the thin film was baked at 50° C. for 10 minutes to form a hole transport layer and a semiconductor nanocrystal layer that is light-emitting.

TAZ was deposited on the completely dried light-emitting layer to form a hole-blocking layer having a thickness of 10 nm, and then Alq3 was deposited on the hole-blocking layer to a thickness of about 30 nm to form an electron transport layer. LiF and aluminum were sequentially deposited on the electron transport layer to thicknesses of 1 nm and 200 nm, respectively, to form an electrode, thereby fabricating the final organic-inorganic hybrid electroluminescence device.

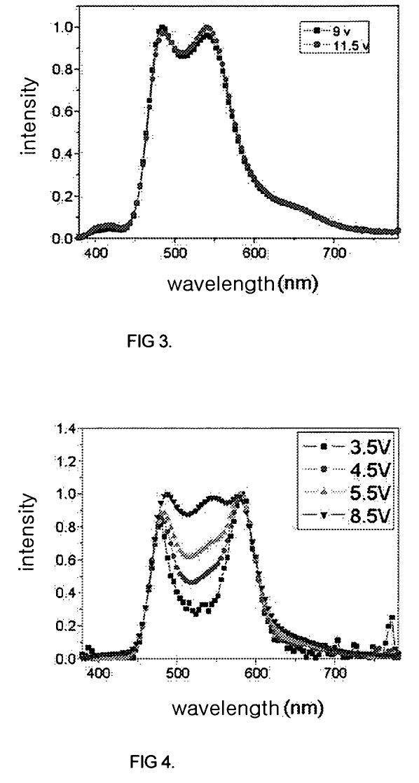

FIG. 3 shows electroluminescence spectra of the organic-inorganic hybrid electroluminescence device in response to the changes in the voltages applied to the device. As shown in FIG. 3, the spectra show that excitons were recombined over the nanocrystal layer and the electron transport layer to simultaneously emit light. In this example, the nanocrystals emitted light at about 480 nm, and the Alq3 emitted light at about 530 nm.

### EXAMPLE 3

### Fabrication of Organic-Inorganic Hybrid Electroluminescence Device Wherein Different Nanocrystals Simultaneously Emit Light

First, a glass substrate on which ITO was patterned was sequentially washed with a neutral detergent, deionized water and isopropyl alcohol, and was then subjected to UV-ozone treatment. TPD, the 470 nm light-emitting nanocrystals prepared in Preparative Example 2, and the 590 nm light-emitting nanocrystals prepared in Preparative Example 3 in a weight ratio of 1:0.5:0.5 were dissolved in chloroform to prepare a 1 wt % solution. The solution was spin-coated on the substrate to form a thin film, and thereafter the thin film was baked at 50° C. for 10 minutes to form a hole transport layer and a semiconductor nanocrystal layer that is light-emitting.

TAZ was deposited on the completely dried light-emitting layer to form a hole-blocking layer having a thickness of 10 nm, and then Alq3 was deposited on the hole-blocking layer to a thickness of about 30 nm to form an electron transport layer. LiF and aluminum were sequentially deposited on the electron transport layer to thicknesses of 1 nm and 200 nm, respectively, to form an electrode, thereby fabricating the final organic-inorganic hybrid electroluminescence device.

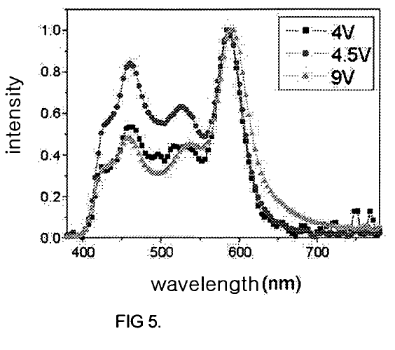

FIG. 4 shows electroluminescence spectra of the organic-inorganic hybrid electroluminescence device in response to the changes in the voltages applied to the device. As shown in FIG. 4, the spectra show that excitons were recombined at the nanocrystal layer to emit light when the applied voltage was low, and excitons were recombined over the nanocrystal layer and the electron transport layer to simultaneously emit light when the applied voltages increased. In this example, the nanocrystals emitted light at about 480 nm and 590 nm.

### EXAMPLE 4

### Fabrication of Organic-Inorganic Hybrid Electroluminescence Device Wherein Hole Transport Layer, Electron Transport Layer and Nanocrystals Simultaneously Emit Light

First, a glass substrate on which ITO was patterned was sequentially washed with a neutral detergent, deionized water and isopropyl alcohol, and was then subjected to UV-ozone treatment. TFB and the 590 nm light-emitting nanocrystals prepared in Preparative Example 3 in a weight ratio of 1:1 were dissolved in chlorobenzene to prepare a 1 wt % solution. The solution was spin-coated on the substrate to form a thin film, and thereafter the thin film was baked at 180° C. for 10 minutes to form a hole transport layer and a semiconductor nanocrystal layer that is light-emitting.

TAZ was deposited on the completely dried light-emitting layer to form a hole-blocking layer having a thickness of 20 nm, and then Alq3 was deposited on the hole-blocking layer to a thickness of about 20 nm to form an electron transport layer. LiF and aluminum were sequentially deposited on the electron transport layer to thicknesses of 1 nm and 200 nm, respectively, to form an electrode, thereby fabricating the final organic-inorganic hybrid electroluminescence device.

FIG. 5 shows electroluminescence spectra of the organic-inorganic hybrid electroluminescence device in response to the changes in the voltages applied to the device. As shown in FIG. 5, the spectra show that excitons were recombined over the hole transport layer, the nanocrystal layer and the electron transport layer to simultaneously emit light. CIE color coordinates are (0.335, 0.359) at 4V, (0.0311, 0.334) at 4.5V, and (0.332, 0.329) at 9V, indicating white light emission. The TFB, the nanocrystals and the Alq3 emitted light at 460 nm, 590 nm, and 530 nm, respectively.

As apparent from the above description, embodiments of the present invention provide a novel white light-emitting organic-inorganic hybrid electroluminescence device comprising semiconductor nanocrystals. The electroluminescence device can be combined with a color filter to manufacture a full color display, can be used as a backlight unit for a liquid crystal display, and can be used to manufacture an illuminator.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A white light-emitting organic-inorganic hybrid electroluminescence device, comprising:
(i) a hole-injecting electrode;
(ii) a hole transport layer;
(iii) a semiconductor nanocrystal layer;
(iv) an electron transport layer; and
(v) an electron-injecting electrode,
formed in this order from the bottom,
wherein the semiconductor nanocrystal layer is composed of at least one kind of semiconductor nanocrystals, and at least one layer selected from the group consisting of the semiconductor nanocrystal layer, the hole transport layer and the electron transport layer, emit light to achieve white light emission.

2. The device according to claim 1, further comprising a hole-blocking layer interposed between the semiconductor nanocrystal layer and the electron transport layer.

3. The device according to claim 1, wherein the semiconductor nanocrystal layer is composed of at least two kinds of nanocrystals having at least one different size, composition, structures or shape.

4. The device according to claim 1, wherein the nanocrystals constituting the semiconductor nanocrystal layer are selected from the group consisting of Group II-IV compound semiconductor nanocrystals, Group III-V compound semiconductor nanocrystals, Group IV-VI compound semiconductor nanocrystals, Group IV nanocrystals, nanocrystals in the state of a simple mixture, core-shell structured nanocrystals, gradient-structured nanocrystals, and nanocrystals in an alloy form when two or more nanocrystals are used to constitute the semiconductor nanocrystal layer.

5. The device according to claim 4, wherein the Group II-IV compound semiconductor nanocrystals comprise CdS, CdSe, CdTe, ZnS, ZnSe, ZnTe, HgS, HgSe and HgTe; the Group III-V compound semiconductor nanocrystals comprise GaN, GaP, GaAs, InP and InAs; the Group IV-VI compound semiconductor nanocrystals comprise PbS, PdSe and PbTe; and the Group IV nanocrystals comprise Si and Ge.

6. The device according to claim 1, wherein the hole-injecting electrode is formed of a material selected from the group consisting of indium tin oxide, indium zinc oxide, nickel, platinum, gold, silver, iridium, and oxides thereof.

7. The device according to claim 1, wherein the hole transport layer is made of a material selected from the group consisting of poly(3,4-ethylenedioxythiophene)/polystyrene para-sulfonate, poly-N-vinylcarbazole derivatives, polyphenylenevinylene derivatives, polyparaphenylene derivatives, polymethacrylate derivatives, poly(9,9-dioctylfluorene) derivatives, poly(spiro-fluorene) derivatives, triarylamine derivatives, copper phthalocyanine derivatives, and starburst-type compounds; and has a thickness of 10 nm to 100 nm.

8. The device according to claim 1, wherein the semiconductor nanocrystal layer has a thickness of 3 nm to 100 nm.

9. The device according to claim 1, wherein the electron transport layer is made of a material selected from the group consisting of oxazoles, isooxazoles, triazoles, isothiazoles, oxydiazoles, thiadiazoles, perylenes, and aluminum complexes; and has a thickness of 10 nm to 100 nm.

10. The device according to claim 1, wherein the electron-injecting electrode is made of a material selected from the group consisting of I, Ca, Ba, Ca/Al, LiF/Ca, LiF/Al, BaF₂/Al, BaF₂/Ca/Al, Al, Mg, and Ag:Mg alloys; and has a thickness of 50 nm to 300 nm.

11. The device according to claim 2, wherein the hole-blocking layer is made of a material selected from the group consisting of imidazoles, phenanthrolines, triazoles, oxadiazoles, and aluminum complexes; and has a thickness of 5 nm to 50 nm.

12. A white light-emitting organic-inorganic hybrid electroluminescence device, comprising:
(i) a hole-injecting electrode;
(ii) a hole transport layer;
(iii) a semiconductor nanocrystal layer;
(iv) an electron transport layer; and
(v) an electron-injecting electrode,
formed in this order from the bottom,
wherein the semiconductor nanocrystal layer is composed of at least two kinds of semiconductor nanocrystals and the semiconductor nanocrystals simultaneously emit light at different wavelengths to achieve white light emission.

13. The device according to claim 12, wherein the at least two kinds of semiconductor nanocrystals have at least one different size, composition, structure or shape.

14. The device according to claim 12, further comprising a hole-blocking layer interposed between the semiconductor nanocrystal layer and the electron transport layer.

15. The device according to claim 12, wherein the nanocrystals constituting the semiconductor nanocrystal layer are selected from the group consisting of Group II-IV compound semiconductor nanocrystals, Group II-V compound semiconductor nanocrystals, Group IV-VI compound semiconductor nanocrystals, Group IV nanocrystals, nanocrystals in the state of a simple mixture, core-shell structured nanocrystals, gradient-structured nanocrystals, and nanocrystals in an alloy form when two or more nanocrystals are used to constitute the semiconductor nanocrystal layer.

16. The device according to claim 15, wherein the Group II-IV compound semiconductor nanocrystals comprise CdS, CdSe, CdTe, ZnS, ZnSe, ZnTe, HgS, HgSe and HgTe; the Group II-V compound semiconductor nanocrystals comprise GaN, GaP, GaAs, InP and InAs; the Group IV-VI compound semiconductor nanocrystals comprise PbS, PdSe and PbTe; and the Group IV nanocrystals comprise Si and Ge.

17. The device according to claim 12, wherein the hole-injecting electrode is formed of a material selected from the group consisting of indium tin oxide, indium zinc oxide, nickel, platinum, gold, silver, iridium and oxides thereof.

18. The device according to claim 12, wherein the hole transport layer is made of a material selected from the group consisting of poly(3,4-ethylenedioxythiophene)/polystyrene para-sulfonate, poly-N-vinylcarbazole derivatives, polyphenylenevinylene derivatives, polyparaphenylene derivatives, polymethacrylate derivatives, poly(9,9-dioctylfluorene) derivatives, poly(spiro-fluorene) derivatives, triarylamine derivatives, copper phthalocyanine derivatives, and starburst-type compounds; and has a thickness of 10 nm to 100 nm.

19. The device according to claim 12, wherein the semiconductor nanocrystal layer has a thickness of 3 nm to 100 nm.

20. The device according to claim 12, wherein the electron transport layer is made of a material selected from the group consisting of oxazoles, isooxazoles, triazoles, isothiazoles, oxydiazoles, thiadiazoles, perylenes, and aluminum complexes; and has a thickness of 10 nm to 100 nm.

21. The device according to claim 12, wherein the electron-injecting electrode is made of a material selected from the group consisting of I, Ca, Ba, Ca/Al, LiF/Ca, LiF/Al, BaF₂/Al, BaF₂/Ca/Al, Al, Mg, and Ag:Mg alloys; and has a thickness of 50 nm to 300 nm.

22. The device according to claim 14, wherein the hole-blocking layer is made of a material selected from the group consisting of imidazoles, phenanthrolines, triazoles, oxadiazoles, and aluminum complexes; and has a thickness of 5 nm to 50 nm.

23. A full-color display comprising the device according to claim 1 and a color filter.

24. A full-color display comprising the device according to claim 12 and a color filter.

25. An illuminator comprising the device according to claim 1.

26. An illuminator comprising the device according to claim 12.

27. A liquid crystal display comprising the device according to claim 1 as a backlight unit.

28. A liquid crystal display comprising the device according to claim 12 as a backlight unit.
